(19) United States
(12) Patent Application Publication
(10) Pub. No.: US 2009/0034353 A1
(43) Pub. Date: Feb. 5, 2009

(54) Semiconductor memory device

(75) Inventors: Seiji Narui, Tokyo (JP); Takeshi Ohgami, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 12/222,105

(22) Filed: Aug. 1, 2008

(30) Foreign Application Priority Data
Aug. 3, 2007 (JP) 2007-203316

(51) Int. Cl. G11C 5/14

(52) U.S. Cl. 365/226

(57) ABSTRACT

A semiconductor memory device includes multiple mats arranged in an array, each including multiple memory cells storing a charge as information, and multiple power-supply lines, one end of each line of the lines being connected in common to an internal power supply which decreases or increases a voltage which is supplied from an external power source. The power-supply lines extend in a given direction in an area in which the multiple mats are formed and the other end of each line of the multiple power-supply lines is connected in common on the edge mat.

### BACKGROUND OF THE INVENTION

1. Field of the Invention

The present invention relates to a semiconductor memory device such as a DRAM (Dynamic Random Access Memory).

2. Description of Related Art

DRAMs which include multiple banks operating independently of one another are known (see Japanese Patent Laid-Open No. 11-007762). FIG. 1 shows a layout of a DRAM.

Referring to FIG. 1, the DRAM includes four banks B0 to B3 that operate independently of one another. Each of banks B0 to B3 includes an X decoder (XDEC) for selecting a word line (WL) and a Y decoder (YDEC) for selecting a bit line (BL). Each of banks B0 to B3 includes multiple mats arranged in a matrix. In each of banks B0 to B3, 33 mats are arranged in the row direction (the direction in which the bit lines extend) and 16 mats are arranged in the column direction (the direction in which the word lines extend).

Mat 10 includes a memory cell array, a sense amplifier section, and a subword driver. The memory cell array includes multiple bit lines provided in parallel with each other at regular spacings, word lines that intersect the bit lines and that are arranged in parallel with each other at regular spacings, and multiple memory cells formed at the intersections between the bit lines and word lines, each including a switch element and a capacitance element.

The sense amplifier section includes multiple sense amplifiers, one for each bit line, and is provided on both sides of the memory cell array. The subword driver includes multiple drive transistors, one for each word line. The subword drivers are provided above and below the memory cell array.

The sense amplifier section and the subword driver are shared by adjacent mats 10.

Sense amplifier drive power-supply lines for supplying power to the sense amplifiers of each mat are formed on the memory cell array section including multiple mats that constitutes the bank. FIG. 2 shows a layout of sense amplifier drive power-supply lines.

The layout shown in FIG. 2 schematically shows multiple mats 10 arranged in the row direction of bank B1 shown in FIG. 1 and sense amplifier drive power-supply lines formed on mats 10. Only five mats are shown in FIG. 2 and the other mats are omitted from FIG. 2.

Four sense amplifier groups (SAGs) 100, into which a sense amplifier section is divided, are arranged in the column direction between adjacent mats 10. Each sense amplifier is supplied with a first voltage (high-level) and a second voltage (low-level) as drive voltages. The sense amplifier determines the information state of charge held in the memory cell on the basis of these voltages.

Provided for each row of SAGs 100 are sense amplifier drive power-supply line 101 for supplying the first voltage to the sense amplifiers and sense amplifier drive power-supply line 102 for supplying the second voltage to the sense amplifiers.

Sense amplifier drive power-supply lines 101 are connected in common at one end in array power-supply wiring area 20a and extend from array power-supply wiring area 20a in the row direction. Each sense amplifier drive power-supply line 101 passes through all mats 10 arranged in the row direction. The other end of sense amplifier drive power-supply line 101 is not connected to any element.

Likewise, sense amplifier drive power-supply lines 102 are connected in common at one end in array power-supply wiring area 20a and extend from there in the row direction. Each sense amplifier drive power-supply line 102 passes through all mats 10 arranged in the row direction and the other end is not connected to any element.

Internal voltage generating circuits 1 and 2 decrease a voltage supplied from an external power source, not shown, to generate the first and second voltages, respectively. Sense amplifier drive power-supply lines 101 are connected to internal voltage generating circuit 1 and sense amplifier drive power-supply lines 102 are connected to internal voltage generating circuit 2.

Provided around the memory cell array section constituting the bank are an X decoder (XDEC) and a Y decoder (YDEC), not shown. The X decoder (XDEC) and the Y decoder (YDEC) designate addresses which are used to write and read data to and from memory cells. Internal voltage generating circuits 1 and 2 are formed on the side of the memory cell array section on which the Y decoder is provided. Array power-supply wiring area 20a is formed between the area in which internal voltage generating circuits 1 and 2 are formed and the area in which the Y decoder is provided.

Power-supply lines for driving the subword drivers are arranged in a layout similar to the layout of the sense amplifier drive power-supply lines described above. The internal voltage generating circuit increases a voltage supplied from an external power source or, in some cases, generates a negative voltage, to generate voltages for driving the subword drivers.

In the case where the voltage for driving a sense amplifier is produced by decreasing a voltage from an external power source by an internal voltage generating circuit, if the resistance of the sense amplifier drive power-supply line is high, the load capacitance of the sense amplifier will be very high, which can cause a significant, temporary drop of the voltage supplied to the sense amplifier drive power-supply line when driving the sense amplifier. As a result, signal level determination by the sense amplifier takes significant time and possibly is not completed in a predetermined time. If the determination is not completed in the predetermined time, a signal cannot accurately be read from the memory cell and the operation of the DRAM becomes unstable. Therefore, in order to achieve a stable operation of the DRAM, it is absolutely necessary to take measures for reducing the resistance of the sense amplifier drive power-supply lines.

In conventional layout designs of mats (memory cell arrays) and sense amplifier drive power-supply lines in memory cell array sections constituting banks, one layout pattern (combination of a memory cell block and wiring block) is repeated to form a layout of the memory cells and sense amplifier drive power-supply lines in order to reduce the amount of mask data used in a layout design system. According to this layout, the mats for patterns of various lines disposed near memory cells, such as bit lines and word lines, including the patterns of sense amplifier drive power-supply lines, can be made exactly the same, and crosstalk noise between the lines during memory cell read and write operations can also be made uniform. This facilitates an optimized design against crosstalk noise on the mats and therefore improves the noise resistance of the whole semiconductor device.

A layout of memory cells and sense amplifier drive power-supply lines designed in this way is the one shown in FIG. 2.

However, the resistances of sense amplifier drive power-supply lines 101, 102 in the layout shown in FIG. 2 are high because the other ends of sense amplifier drive power-supply lines 101, 102 are not connected to any elements. Therefore, the DRAM having the layout shown in FIG. 2 has a problem in which the operation of the DRAM becomes unstable because of the high resistance of the sense amplifier drive power-supply lines.

The resistances of sense amplifier drive power-supply lines 101, 102 in the layout shown in FIG. 2 can be reduced by connecting the other ends of sense amplifier drive power-supply lines 101, 102 in common. However, this poses another problem as described below.

FIG. 3 schematically shows a layout in which the other ends of sense amplifier drive power-supply lines 101 are connected together in common.

If the layout of mats 10 (memory cell arrays) and sense amplifier drive power-supply lines 101 is formed by repeating the same layout pattern, sense amplifier drive power-supply lines 101 pass through all mats 10 arranged in the row direction. The other ends of sense amplifier drive power-supply lines 101 are located beyond edge mat 10a. Accordingly, array power-supply wiring area 20c that connects the other ends of sense amplifier drive power-supply lines 101 together is formed outside edge mat 10a column (outside the area of the memory cell array section). That is, array power-supply wiring areas 20a, 20c are formed on both sides of the memory cell array section.

In the DRAM in which array power-supply wiring areas are provided on both sides of a memory cell array section, array power-supply wiring area 20a for one memory cell array section and array power-supply wiring area 20c for the other memory cell array section are formed in the area between the adjacent memory cell array sections. Formation of the two array power-supply wiring areas between adjacent memory cell array sections in this way inhibits chip size reduction.

### SUMMARY

The present invention seeks to solve one or more of the above problems, or to improve upon those problems at least in part.

In one embodiment, there is provided a semiconductor memory device that includes multiple mats arranged in an array, each including multiple memory cells storing a charge as information; and multiple power-supply lines, one end of each line of the multiple power-supply lines being connected in common to an internal power supply which decreases or increases a voltage that is supplied from an external power source; wherein the multiple power-supply lines extend in a given direction in an area in which the multiple mats are formed and the other end of each line of the multiple power-supply lines is connected in common on a mat which is located at the endmost position in the given direction among the multiple mats.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a schematic diagram showing a layout of a DRAM;

FIG. 2 is a block diagram showing a layout of sense amplifier drive power-supply lines;

FIG. 3 is a schematic diagram illustrating how the other ends of the sense amplifier drive power-supply lines in the layout shown in FIG. 2 are connected together in common;

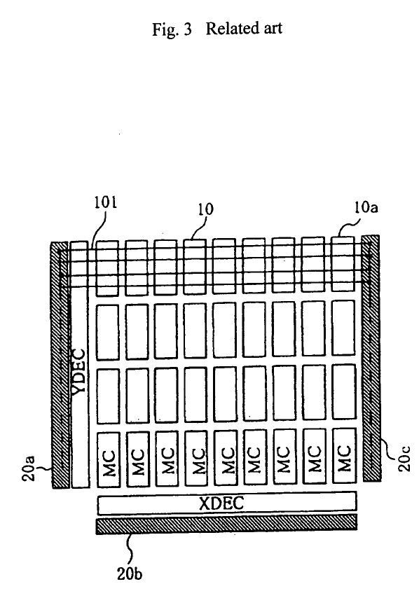

FIG. 4 is a schematic diagram showing a configuration of a semiconductor memory device, which is one exemplary embodiment of the present invention;

FIG. 5 is a block diagram showing a layout of power-supply lines formed on a memory cell array section;

FIG. 6 is a block diagram showing connections of the sense amplifier drive power-supply lines, SAGs, and mats in the layout shown in FIG. 5;

FIG. 7 is a circuit diagram showing a configuration of sense amplifiers; and

FIG. 8 is a schematic diagram illustrating wiring directions of power-supply lines in a multilayer structure in the memory cell array section shown in FIG. 4.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

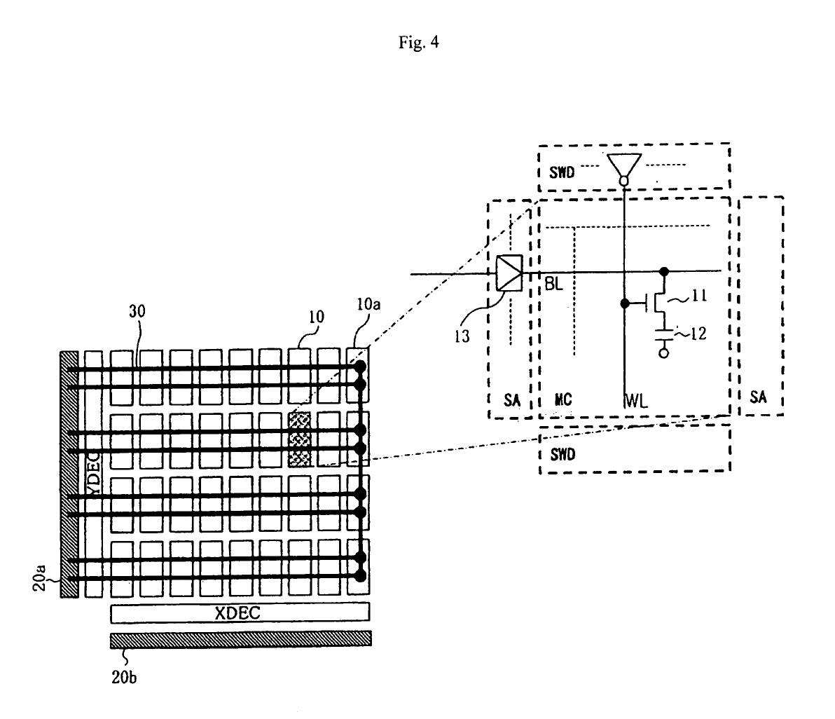

Referring to FIG. 4, a semiconductor memory device according to a first embodiment of the present invention, which is a semiconductor memory, such as a DRAM including multiple banks that operate independently of one another, has a memory cell array section including multiple mats 10 arranged in a matrix. While mats 10 are arranged in a simplified matrix of 4 rows and 9 columns, the present invention is not limited to the arrangement.

Mats 10 have the same configuration, each including memory cell array MC, sense amplifier section SA, and subword driver SWD.

Memory cell array MC includes multiple bit lines BL provided in parallel with each other at regular spacings, multiple word lines WL intersecting bit lines BL and being arranged in parallel with each other at regular spacings, and multiple memory cells formed at the intersections between bit lines BL and word lines WL, each including switch element 11 and capacitance element 12. Switch element 11 may be a MOS (Metal Oxide Semiconductor) transistor. Capacitance element 12 may be a capacitor. Switch element 11 has one terminal which is connected to bit line BL and the other terminal which is connected to capacitance element 12. A control terminal of switch element 11 is connected to word line WL.

Sense amplifier section SA includes multiple sense amplifiers 13, one for each bit line BL. Sense amplifier sections SA are disposed on both sides of the memory cell array section. Subword driver SWD includes multiple drive transistors, one for each word line. Subword drivers SWD are disposed above and below the memory cell array MC. Bit line BL and the sense amplifier connected to bit line BL are staggered with each other so that sense amplifier section SA can be shared between adjacent mats 10.

Likewise, for subword driver SWD, word line WL and a drive transistor connected to word line WL are staggered so that subword driver SWD can be shared between adjacent mats 10. The arrangement of sense amplifier section SA and the bit line and the arrangement of subword driver SWD and the word line are not limited to the staggered arrangement but they may be disposed in another arrangement.

In addition to signal lines used for controlling memory cells, power-supply lines 30 are formed on the memory cell array section for supplying a voltage generated by an internal voltage generating circuit, not shown, to the sense amplifiers. Power-supply lines 30 are multiple power-supply lines extending in the row direction. Power-supply lines are connected in common at one end in array power-supply wiring area 20a and the other ends of power-supply lines are connected in common in an area on edge mat 10a at the edge of the memory cell array section opposite to the side on which array power-supply wiring area 20a is formed.

Array power-supply wiring area 20a is an area for connecting power-supply lines 30 to an external power source pad or internal voltage generating circuits around the memory cell array section and is formed in the direction in which the word lines extend.

Although not shown in FIG. 4, multiple power-supply lines for driving subword drivers SWD are formed on the memory cell array section. The power-supply lines are connected in common at one end in array power-supply wiring area 20b and the other ends of the power-supply lines are connected in common in an area of the edge mat column at the edge of the memory cell array section opposite to the side on which array power-supply wiring area 20b is formed. Array power-supply wiring area 20b is an area for connecting the power-supply lines to an external power source pad and to an internal voltage generating circuit around the memory cell array section and is formed in the direction in which the bit lines extend.

An X decoder (XDEC) and a Y decoder (YDEC) are provided around the memory cell array section. The X decoder (XDEC) and the Y decoder (YDEC) designate addresses which are used to write and read data to and from memory cells. The Y decoder is formed along the direction in which the word lines extend and X decoder is formed along the direction in which the bit lines extend.

Because the other ends of power-supply lines 30 are connected in common in the layout described above, the resistance of power-supply lines 30 is reduced and consequently, stable operation of the DRAM can be achieved.

Furthermore, because the other ends of power-supply lines 30 are connected in common on edge mat 10a, array power-supply wiring areas do not need to be provided on both sides of the memory cell array section. Accordingly, the size of the chip is smaller than a chip on which array power-supply wiring areas are provided on both sides of a memory cell array section.

In the layout design of power-supply lines 30, a layout pattern used for edge mat 10a differs from the layout pattern of the other mats 10. Crosstalk noise from power-supply lines to the memory cell array can occur on edge mat 10a because the power-supply lines are arranged in a hook-like pattern. Since memory cells have been reduced in size in recent years, the gap between metal interconnects (signal lines such as word lines and bit lines) formed in a grid pattern on the memory cell arrays has become very small. A metal interconnect layer with such a small gap between the interconnects in a grid pattern acts as a shield against noise from power-supply lines (electromagnetic radiation noise) because the shield effect is so high that the use of the hook-like pattern does not cause the problem of crosstalk noise from power-supply lines to memory cell arrays.

As with the power-supply lines for driving sense amplifiers, in the power supply lines for driving subword drivers, if a resistance of internal power supply lines increases, it causes, due to the large load capacity, problems such as an extremely slow rise of electric potential of a selected word line, resulting in unstable operation of the DRAM. In the exemplary embodiment, the power-supply lines for driving the subword drivers are also connected in common at the other end and therefore stable operation of the DRAM can be achieved. Furthermore, because array power-supply wiring areas do not need to be provided on both sides of the memory cell array section, the chip size can be reduced.

Details of a structure of the memory cell array section of the semiconductor memory device according to the exemplary embodiment will be described below.

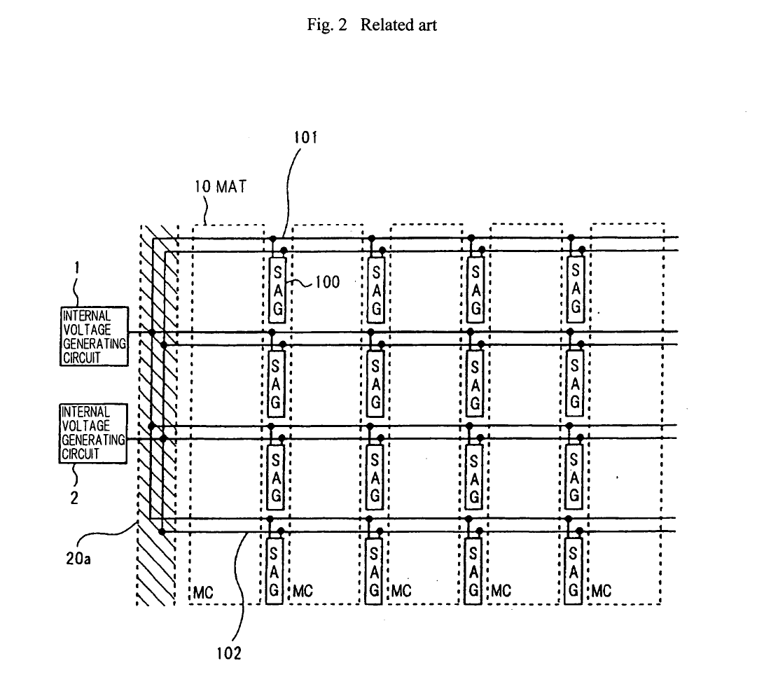

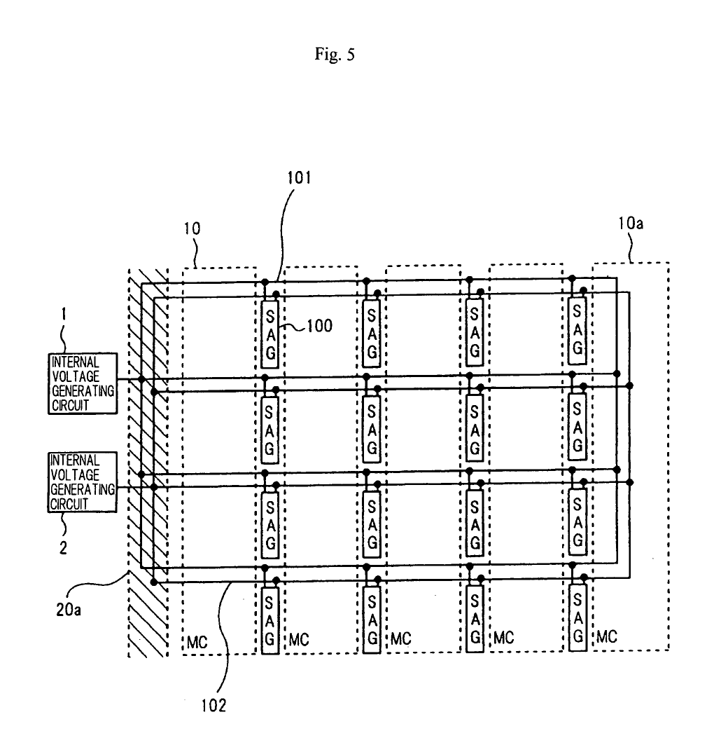

FIG. 5 is a schematic diagram showing a layout of power-supply lines formed on a memory cell array section. The layout of the power-supply lines shown in FIG. 5 is the same as the layout shown in FIG. 2 except that the other ends of the sense amplifier drive power-supply lines are connected together in common on edge mat 10a.

Four SAGs 100 are formed between mats. Four SAGs 100 are four groups of sense amplifiers 13 constituting sense amplifier section SA shown in FIG. 4. Each SAG 100 includes multiple sense amplifiers 13.

Sense amplifier drive power-supply lines 101, 102 are provided for each row of SAGs 100. Sense amplifier drive power-supply lines 101 are connected together in common at one end in array power-supply wiring area 20a and extend from there in the row direction. The other ends of sense amplifier drive power-supply lines 101 are connected in common on edge mat 10a. Similarly, sense amplifier drive power-supply lines 102 are connected together in common at one end in array power-supply wiring area 20a and extend from there in the row direction. The other ends of sense amplifier drive power-supply lines 102 are connected together in common on edge mat 10a.

Internal voltage generating circuits 1 and 2 decrease a voltage supplied from an external power source, not shown, to generate first and second voltages, respectively. Sense amplifier drive power-supply lines 101 are connected to internal voltage generating circuit 1 and sense amplifier drive power-supply lines 102 are connected to internal voltage generating circuit 2. The first voltage is supplied from internal voltage generating circuit 1 to SAGs 100 through sense amplifier drive power-supply lines 101. The second voltage is supplied from internal voltage generating circuit 2 to SAGs 100 through sense amplifier drive power-supply lines 102. Sense amplifier 13 in SAG 100 determines the signal level of a charge held in the memory cell on the basis of the first and second voltages supplied from internal voltage generating circuits 1 and 2.

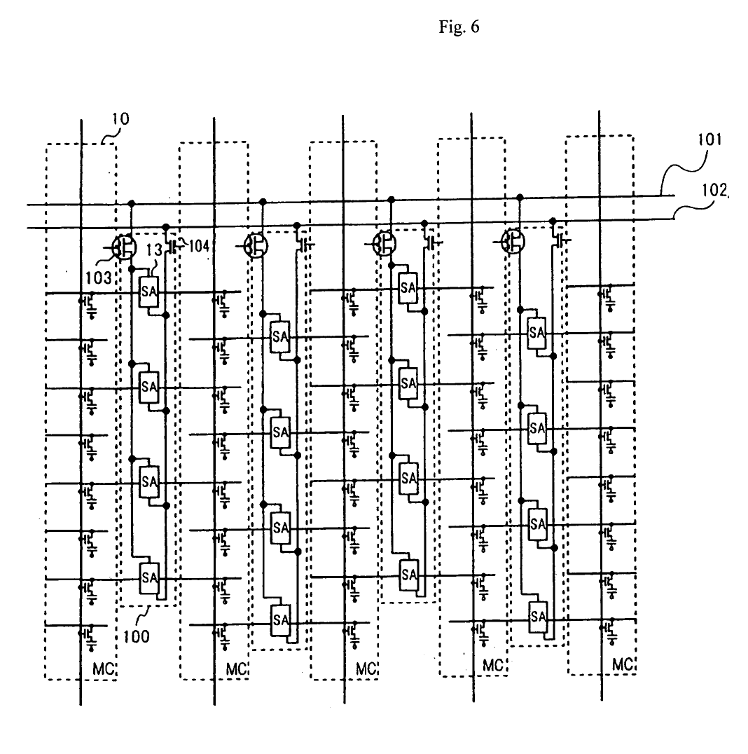

FIG. 6 shows a configuration of SAGs 100 and mats 10 connected to sense amplifier drive power-supply lines 101, 102.

Referring to FIG. 6, SAG 100 includes four sense amplifiers 13. A first voltage input terminal of each of sense amplifiers 13 is connected to a first common line, and a second voltage input terminal of sense amplifier 13 is connected to a second common line. One end of the first line is connected to sense amplifier drive power-supply line 101 through switch element (pMOS) 103. One end of the second line is connected to sense amplifier drive power-supply line 102 through switch element (nMOS) 104. Supply of first and second voltages to sense amplifiers 13 can be controlled by controlling switch elements 103 and 104.

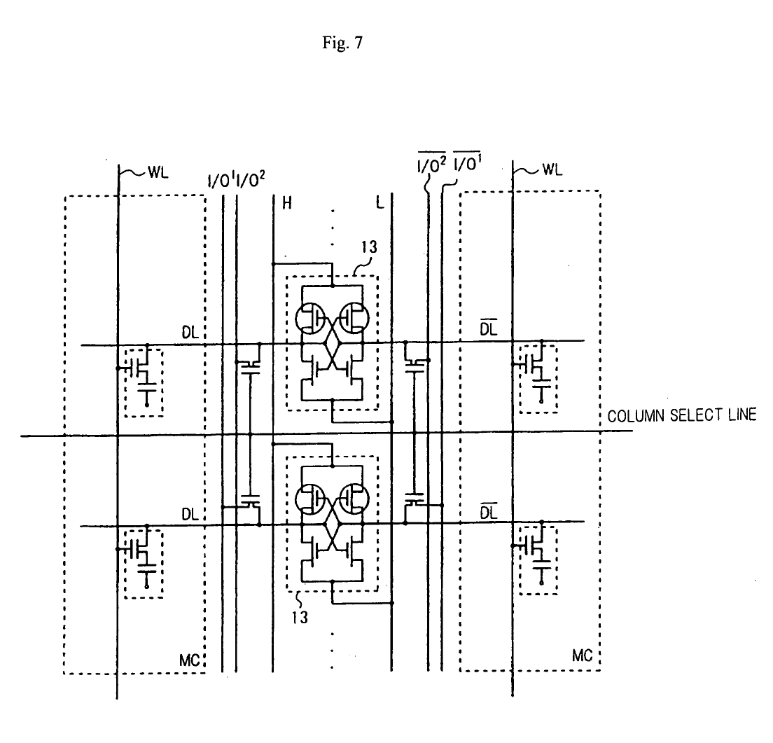

FIG. 7 shows a configuration of a sense amplifier. Referring to FIG. 7, sense amplifier 13 includes the first and second circuits which are symmetrically arranged. Each of the first and second circuits comprises pMOS and nMOS transistors. The drain (or source) terminal of the pMOS transistor is connected to the source (or drain) terminal of the nMOS transistor. The control terminal of the pMOS transistor is connected to the control terminal of the nMOS transistor. A connection line between the drain (or source) terminals is connected to the bit line of the memory cell provided on one side, and a connection line between the control terminals is connected to the bit line of the memory cell provided on the other side. The other terminal (drain/source) of each pMOS transistor is connected to the first line shown in FIG. 6. The other terminal (drain/source) of each nMOS transistor is connected to the second line shown in FIG. 6. The sense amplifier having such a configuration is known as a flip-flop sense amplifier.

First and second I/O lines are provided on both sides of the row of sense amplifiers 13 in parallel with word lines WL. Column select line 105 is provided between sense amplifiers 13 in parallel with the bit lines.

Because sense amplifier drive power-supply lines 101, 102 are connected in common at the other end in the layout described above, the resistances of sense amplifier drive power-supply lines 101, 102 are reduced. As a result, stable operation of the DRAM can be achieved.

Furthermore, because sense amplifier drive power-supply lines 101, 102 are connected at the other end in common on edge mat 10a, array power-supply wiring areas do not need to be provided on both sides of the memory cell array section. Accordingly, the chip size can be reduced as compared with a chip on which array power-supply wiring areas are provided on both sides of a memory cell array section.

If the second voltage in the configuration shown in FIG. 5 is to be made equal to a ground potential, sense amplifier drive power-supply lines 102 are grounded. In this case, internal voltage generating circuit 2 is not required.

In addition to the effects described above, the reduction of resistance of the power-supply lines according to the exemplary embodiment has the following effects.

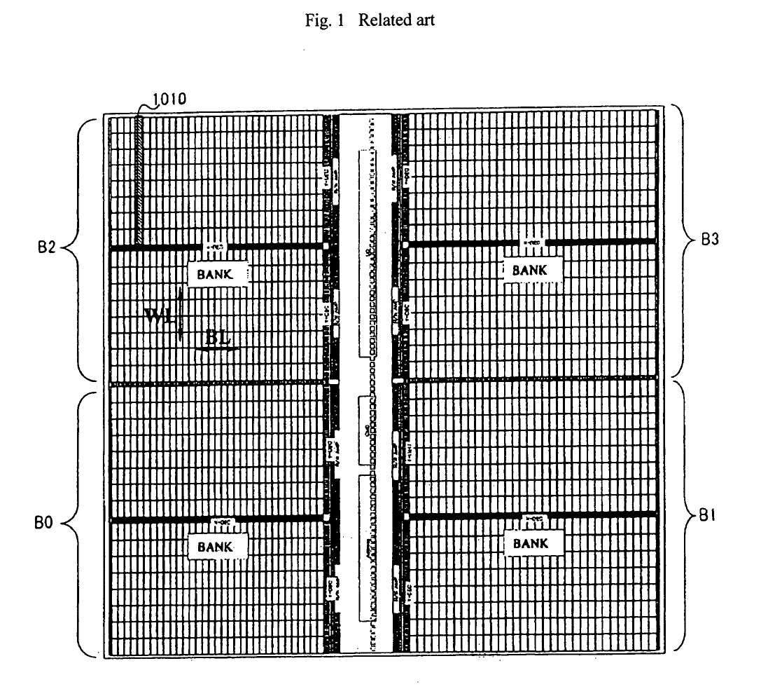

In the DRAM shown in FIG. 1, the multiple sense amplifiers on each of the mats constituting a bank are selected and activated along the word line direction (activated mat column 1010). Current consumption is concentrated in the direction of the activation which is the direction in which the sense amplifiers are selected (direction in which the word lines extend). According to the exemplary embodiment, more power-supply lines formed on the memory cell array are formed in the direction intersecting (orthogonal to) the activation direction in which current consumption is concentrated (in the direction in which bit lines extend) than are formed in the activation direction and, in addition, the resistance of the power-supply lines is reduced. Therefore signal integrity can be further improved.

In order to form more power-supply lines in the direction intersecting the activation direction than in the activation direction, a multilayer interconnection is effective. By forming the power-supply lines shown in FIG. 4 and sense amplifier drive power-supply lines 101, 102, shown in FIG. 5, in multiple layers, the resistances of the lines can be further reduced.

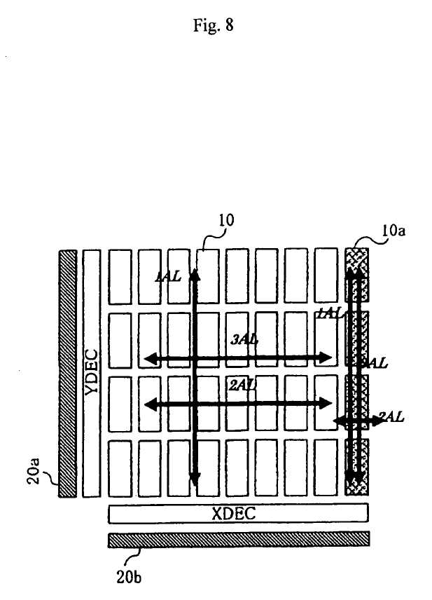

FIG. 8 schematically shows the wiring directions in a multilayer structure of power-supply lines in the memory cell array section shown in FIG. 4.

Referring to FIG. 8, power-supply lines 30 are formed in first to third aluminum interconnect layers. In the areas in the memory cell array section excluding the area of edge mat 10a, the second and third aluminum interconnect layers extend in the row direction whereas the first aluminum interconnect layer extends in the column direction. The multilayer interconnect structure enables more power-supply lines to be formed in the direction intersecting the activation direction. Accordingly, the resistances of power-supply lines can be further reduced by using the second and third aluminum interconnect layers as power-supply lines and by connecting the power-supply lines in parallel, for example.

In the area of edge mat 10a column, the first and third aluminum interconnect layers extend in the column direction and the second aluminum interconnect layer extends in the row direction. This enables a structure in which power-supply lines are connected in common on edge mat 10a to be readily implemented.

The width of the power-supply lines formed on edge mat 10a may be wider than the power-supply lines formed on the other mats. This can further reduce the resistances of the power-supply lines.

According to the present invention, the resistance of power-supply lines is reduced because the other ends of the power-supply lines are connected together in common and therefore a semiconductor memory device (DRAM) that operates stably can be provided.

Furthermore, because the other ends of the power-supply lines are connected together in common on the edge mat, the need for providing array power-supply wiring areas on both sides of a memory cell array section is eliminated. Accordingly, the chip size can be reduced as compared with a chip on which array power-supply wiring areas are provided on both sides of a memory cell array section.

It is apparent that the present invention is not limited to the above embodiments, but may be modified and changed without departing from the scope and spirit of the invention.

What is claimed is:

1. A semiconductor memory device comprising:
a plurality of mats arranged in an array, each including a plurality of memory cells which store a charge as information; and
a plurality of power-supply lines, one end of each line of the plurality of power-supply lines being connected in common to an internal power supply which decreases or increases a voltage that is supplied from an external power source;
wherein the plurality of power-supply lines extend in a given direction in an area in which the plurality of mats are formed and the other end of each line of the plurality of power-supply lines is connected in common on a mat which is located at the endmost position in a given direction among the plurality of mats.

2. The semiconductor memory device according to claim 1, wherein each of the plurality of mats comprises a plurality of sense amplifiers for reading information from the plurality of memory cells; and
the plurality of power-supply lines supply a drive voltage to the plurality of sense amplifiers.

3. The semiconductor memory device according to claim 1, wherein a width of a power-supply line which is formed on the mat which is located at the endmost position is wider than a width of a power-supply line which is formed on the other mats.

4. The semiconductor memory device according to claim 2, wherein a width of a power-supply line which is formed on the mat which is located at the endmost position is wider than a width of a power-supply line which is formed on the other mats.
